(19) United States
(12) Patent Application Publication
(10) Pub. No.: US 2002/0119655 A1
(43) Pub. Date: Aug. 29, 2002

(54) Process for treating high aspect ratio structures

(76) Inventor: Yu-Tsai Liu, Hsin-chu (TW)

Correspondence Address: Hung Chang Lin, 8 Schindler Court, Silver Spring, MD, 20903, US

(21) Appl. No.: 09/810,553

(22) Filed: Mar. 19, 2001

Related U.S. Application Data
(63) Continuation-in-part of application No. 09/438,404, filed on Nov. 12, 1999, now abandoned.

(51) Int. Cl. B05D 7/22; B05D 5/12; C23C 16/00; H01L 21/44

(52) U.S. Cl. 438/668; 438/677; 427/58; 427/99; 427/97; 427/237; 427/248.1

(57) ABSTRACT

The present invention provides a process comprising the steps of:

A. providing a substrate having a surface and at least one opening with a high aspect ratio in the surface;

B. providing a vaporized first chemical into the aforesaid at least one opening to be condensed and thereby formed a precursory layer; and

C. providing a second chemical into the aforesaid at least one opening to achieve the purposes of cleaning, etching or coating.

The precursory layer can help the sub-sequential chemical A to be easily filled into the high aspect ratio structure and therefore achieving the purpose of cleaning, etching or coating.

### FIELD OF THE INVENTION

The invention relates to an improved process of cleaning, etching, developing or coating high aspect ratio structures. More particularly, the invention relates to a process that a liquid chemical is vaporized and then condensed to be initially absorbed on a substrate surface with a high aspect ratio structure and then followed by respective treatment to achieve the purpose of cleaning, coating, developing or etching.

### BACKGROUND OF THE INVENTION

As semiconductor technology advanced, circuit elements and interconnections on wafers or silicon substrates become much denser. In order to prevent unwanted interactions between these circuit elements, insulator filled gaps or trenches are provided to physically and electrically isolate the elements and conductive lines. However, as circuit densities continue to increase, the widths of these gaps decrease, thereby increasing gap aspect ratios, typically defined as the gap height divided by the gap width, as a result, cleaning, coating, developing, or etching these narrower gaps becomes more difficult.

In particular, high aspect ratio structures or trenches are important to the function of the device. Therefore, it is essential that the trench can be cleaned, coated, developed or etched thoroughly for proper functioning. It is generally difficult to get materials into and out of high aspect ratio structures, such as trench capacitors, due to surface tension, contact angle, and certain unique geometric considerations. In particular, high aspect ratio structures can have a huge differential in dimensional ratio (i.e., 40:1 differential). The problems are exacerbated when the high aspect ratio structures are extremely small, such as those located on semiconductor wafers.

There are methods disclosed in the prior art for cleaning, coating, developing and etching wafer surfaces which include megasonics, condensed-phase processing, and excimer laser beam irradiation. Megasonics is only effective for particle removal, and it can not be applied in etching or coating process for high aspect ratio structures.

Condensed-phase processing is a method for getting a reactant onto a wafer surface and then removing it. This process provides for suitable process gases to condense and form a film on a cool substrate surface. The condensation is followed by a pulsed process energy source which is used to thermally activate the surface and provide for rapid evaporation of the film. Although effective, this process is again only applicable to relatively flat wafer surfaces. In addition, this process is only effective on volatile species, and not for particle removal. It is believed that contaminants or foreign materials lodged in the trench structures are resistant to this evaporation cleaning process.

Excimer laser beam irradiation is a vapor phase system that attempts to remove surface particles by using a laser beam to scan the substrate within which the trench is formed. Although effective, the process requires a scan of the entire substrate and has several significant drawbacks. First, this process is only effective on relatively flat wafer surfaces. Second, excimer lasers are expensive and require significant additional costs to maintain and operate. Third, the scanning process itself may cause local thermal stresses that adversely affect the physical characteristics and performance of the substrate. Finally, this process is only applicable to particle removal.

In recent technological efforts, attempts have been made to introduce sophisticated directional etching or deposition processes in commercial semiconductor fabrication. These processes incorporate the use of molecular beam technology. This technology has not been effective in, for example, providing uniform deposition, which is necessary for proper coating of high aspect ratio structures. Therefore, there is a need for a better process of removing material from or coating material onto high aspect ratio structures. Such structures are becoming more and more common in many industries and, in particular, the semiconductor industry.

Grebinske (U.S. Pat. No. 4,695,327) in combination with Gale (U.S. Pat. No. 5,966,631). Grebinske in U.S. Pat. No. 4,695,327 teaches treatment by a condensable solvent to remove the impurities in a recess but fails to teach utilizing the process with high aspect ratio holes. Gale in U.S. Pat. No. 5,966,631 teaches a forced plug for high aspect ratio. In either case, single application of the etching chemical is processed. This single condensation, like dew deposited on a cold window at night, tends to ball and does not assure that the etching chemical covers all surfaces of the hole evenly.

### SUMMARY OF THE INVENTION

To meet this and other needs, and in view of its purposes, the present invention provides a process comprising the steps of

A. providing a substrate having a surface and at least one opening with a high aspect ratio in said surface,

B. providing a vaporized first chemical into said at least one opening to be condensed and thereby forming a precursory layer; and

C. providing a second chemical into said at least one opening to achieve the respective purpose of cleaning, etching, developing or coating.

The feature of this invention is to use two layers of chemicals: a first layer of precursory chemical for pre-wetting the surfaces in the hole and a second layer of chemical for spreading the second liquid chemical to cover all surfaces of the high aspect ratio holes and for cleaning, coating, etching, or developing the surface pf the hole. The two steps are to increase the adhesion between the liquid chemical and the pre-wet chemical. The pre-wet chemical has a common component as the subsequent liquid chemical, especially the solvent.

It is to be understood that both the foregoing general description and the following detailed description are exemplary, but are not restrictive, of the invention.

### BRIEF DESCRIPTION OF THE DRAWINGS

The above and other objects and the features and effects of the present invention can be best understood by referring to the following detailed description of the preferred embodiment and the accompanying drawings, in which:

The invention is best understood from the following detailed description when read in connection with the accompanying drawing. It is emphasized that, according to common practice, the various features of the drawings are not to scale. On the contrary, the dimensions of the various features are arbitrarily expanded or reduced for clarity. Included in the drawing are the following figures:

FIGS. 1A and 1B are a cut-away and a cross-sectional view of a high aspect ratio structure within a substrate, respectively, showing a liquid chemical formed on the surface of the substrate;

FIG. 2 is a cross-sectional view showing a condensed precursory layer formed inside the opening of a high aspect ratio structure in accordance with the present invention; and

FIG. 3 is a cross-sectional view showing a chemical filling the opening for the purpose of cleaning, coating or etching in accordance with the present invention.

FIG. 4 shows an exemplified configuration of a process chamber, which can be used in the process in accordance with the present invention; and

FIGS. 5A and 5B show the non-uniformity of the film deposited on the substrate in the prior art and in the present invention, respectively.

### DETAILED DESCRIPTION OF THE PREFERRED EMBODIMENTS

The invention generally comprises a process for removing material from and depositing material into a high aspect ratio structure. The process basically has two steps: a pre-wet step and a spreading step. The process begins by forming a condensed precursory layer onto a high aspect ratio structure by vaporizing a first chemical into a process chamber which is kept in a saturated vapor pressure. Thereafter, a second chemical, which comprises at least one composition same as the first chemical, is introduced into the high aspect ratio structure to achieve for purposes such as removing contaminants from the structure, etching the walls of the structure, and coating material onto the walls of the structure.

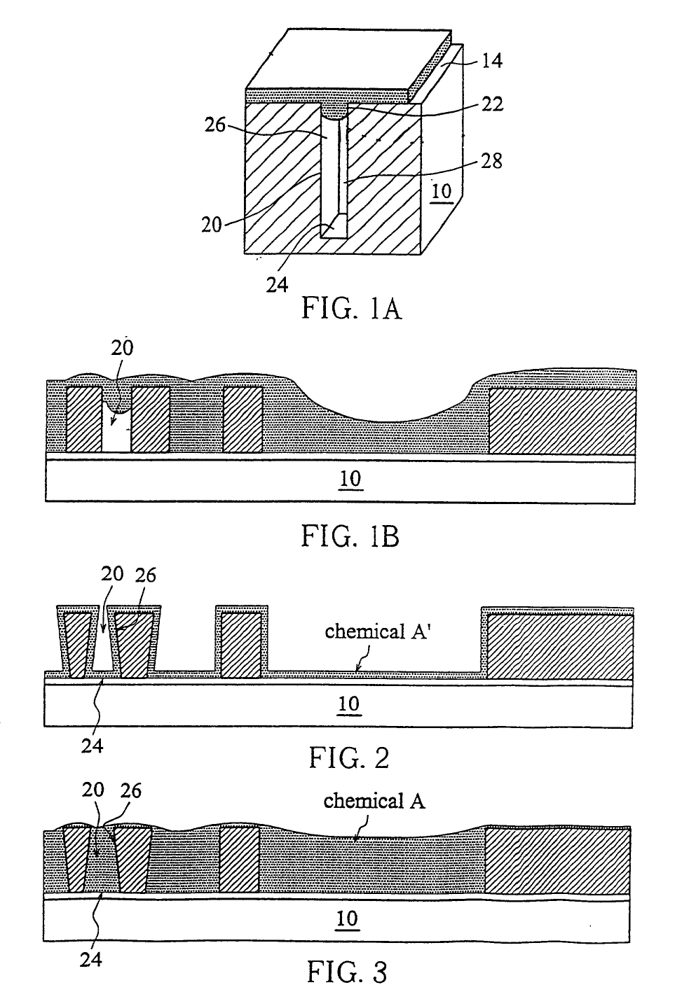

Referring now to the drawing, wherein like reference numerals refer to like elements throughout, FIG. 1A shows a substrate 10 having a surface 14. Although the process of the invention is preferably used on semiconductor wafer substrate, the process is applicable to any other substrate which contains high aspect ratio structures and which may require treatment such as that provided by the process of the invention. Also depicted in FIG. 1A is a high aspect ratio structure 20 which is formed within the substrate 10 (a portion of the substrate 10 has been cut away in the drawing in order to view the interior of the high aspect ratio structure 20). Generally, a high aspect ratio structure 20 extends into the substrate 10 from the surface 14, and comprises an open top 22, a bottom 24, and at least one side wall 26, extending from the top 22 to the bottom 24 of the structure 20. The side walls 26 and the bottom 24 define an interior 28. The high aspect ratio structure 20 can be shaped in any number of ways, such as oval, circular, elongated, rectangle, etc., any of which is treatable by the process of the invention. The particular construction of the high aspect ratio structure 20 depicted in the drawing is simplistic and comprises four side walls 26 which form a parallelogram shaped interior 28.

In the prior art, due to surface tension and certain unique geometric considerations, the interior 28 of structure 20 depicted in FIG. 1A is not easy to be fully covered with chemical to achieve purposes of cleaning, coating, developing or etching. The chemical cannot get into the interior bottom 24 and side walls 26, and usually it is only formed on the surface of the substrate 14 and stay on the open top 22 of the structure 20. As a result, the material inside the structure 20 can not be removed out by applying cleaning or etching chemical, and material can not be filled inside the structure to perform the purpose such as dielectric deposition in the trench application.

In the present invention, chemical A′ is pre-prepared from e.g. the solvent of chemical A utilized for the purpose of cleaning, coating, developing or etching the structure 20. In one embodiment of SOG material from Allied Signal ACCUFLO X138, which is an organic polymer solution developed as a spin-on coating for global planarization, is comprised by composition of Si(OH)_{X}, SiO₂ and solvents. Wherein the solvents comprising Methyl isobutyl ketone can be used as the first chemical A′, and the ACCUFLO X138 is used as the second chemical A for the purpose of spin-on coating. Another example is a polyimide material T6017 from Dupont Electronics containing the solvent system of N-Methyl-2-Pyrrolidone/Methyl Isobutyl Ketone which can be used as chemical A′ when using the above-mentioned T-6017 as chemical A for coating purpose. The process of the invention is depicted by the sequence shown in FIGS. 2-3, and is as follows. Initially, as shown in FIG. 2, the liquid chemical A′ is vaporized and then condensed onto the surface of the substrate 10 and also on the interior surfaces 24 and 26 to form e.g. a precursory layer. Then, chemical A is dispensed on the same substrate 10 to achieve the purpose such as cleaning, coating, developing or etching as shown in FIG. 3.

For purposes of this invention, the term liquid is generally defined as a material in pure form or with a second material dissolved therein. For the process to function properly, it is important that the liquid chemical A′ comprises a liquid which can tolerate the rigors of the process, and it will not change the integrity of the chemical A. The liquid chemical A′ may comprise different liquids, depending upon various factors. For instance, contact angle, surface tension, and partially upon the substrate material. For example, where the substrate material is hydrophobic (i.e., bare silicon semiconductor wafers), a preferred liquid is purified water because the contact angle is very close to 90 degree. Alternatively, when contaminants are to be removed from the high aspect ratio structure 20, a mixture containing 95% water and 5% cleaning agent, for example, is satisfactory. Although a variety of liquid chemical A′ may be used, depending upon the substrate and the process that is being performed, the essential features of the chemical A′, as described above, will remain at least one composition is the same as chemical A.

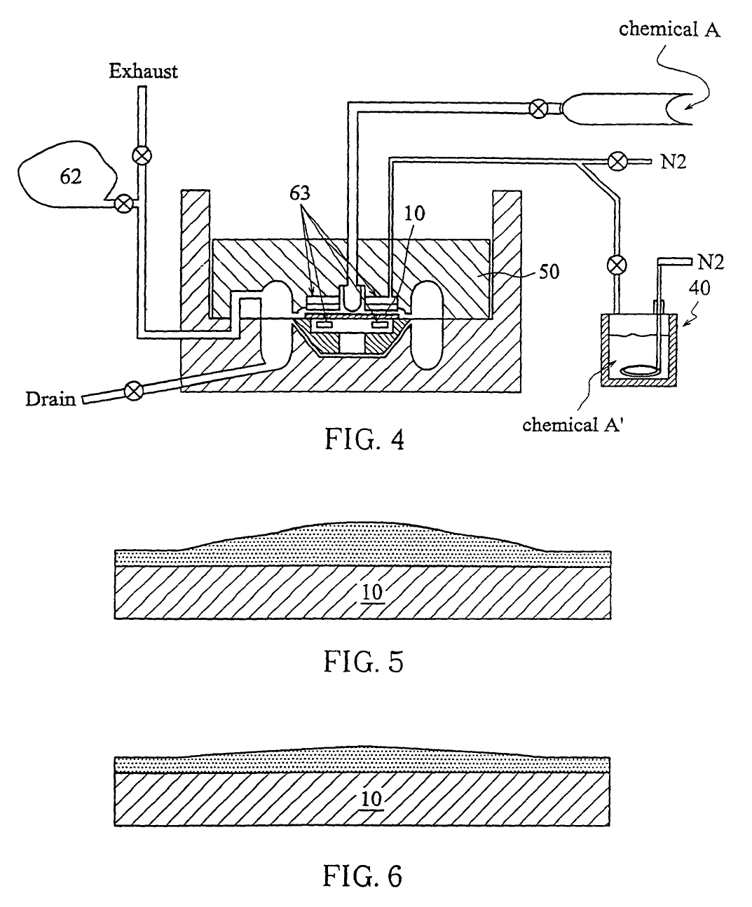

In a preferred embodiment, a coating process is performed on the substrate 10 within a closed process chamber 50. A closed process chamber 50 allows one having ordinary skill in the art to manipulate pressurization and vapor deposition in a controlled fashion. One exemplified configuration of the process chamber 50 is shown in FIG. 4 without to scale, and it can also be referred to Taiwan patent application No. 88115948 filed Sep. 14, 1999 and application No. 88115700 filed Sep. 9, 1999. FIG. 4 shows a closed process chamber 50, a substrate 10, a vacuum pump 62, and megasonics 63. During the process, chemical A′ is vaporized into a higher temperature than the substrate 10 by a heating element 40 in order to condense onto the substrate 10. And the process chamber 50 is pumped down to 1˜20 torrs before the wafer getting into there, and then it is kept in a saturated vapor pressure (more than 1 atmosphere) after chemical A′ is added into the chamber and being maintained as the same throughout the process of applying chemical A. As a result, the solvent of chemical A can be kept balanced inside the process chamber 50, and it will not decrease with time due to volatilizing. And the composition of chemical A, which is already distributed on the substrate 10, can be kept stable. In the prior art, especially in a thin film deposition process, the film deposited by chemical A is easy to become non-uniform both in the film thickness and film property due to the solvent inside is easily evaporated out from the film, especially on the edge of the substrate, as shown in FIG. 5A. However, when the process chamber is kept in a saturated vapor pressure, the film deposited on the substrate can be kept more uniform since the solvent will not decrease in the edge of the wafer.

In any situation where a high aspect ratio structure needs treatment, it is generally preferred that the process be repeated several times. In particular, repeated cycling of the condensation of the first chemical A′ should be utilized to fully and effectively complete the application of the second chemical A, whether it is removal, etching, or coating of a high aspect ratio structure.

Also, during the process in dispensing chemical (A′ or A), the substrate is preferred to be kept in spinning. For example, in dispensing chemical A, the substrate can be spun at a high rotational speed (preferably 1000 rpm) depending upon the geometry of the high aspect ratio structure 20, the viscosity of the chemical A, and the contact angle of the surface 14. Again, megasonics or ultrasonics can be used together with the wafer spinning to improve the uniform distribution of chemical A. And, Nitrogen or hot Nitrogen gas can be used to purge the wafer in the final step to improve wafer drying; dehydration baking of the wafer before the process beginning is also preferred in improving the process performance.

To sum up, the key difference between the present invention is to apply two chemical steps: a pre-wet step and spreading step. There are some advantages in the process for treating high aspect ratio structures in accordance with the invention:

1. Before performing cleaning, coating, developing or etching, a precursory layer is formed on the interior surfaces of the structure with a high aspect ratio by vaporizing a chemical A′. The precursory layer can help the sub-sequential chemical A to be easily filled into the high aspect ratio structure.

2. There is at least one composition the same between chemical A and A′. As a result, the integrity of the chemical A will not be changed when it is distributed onto the substrate surface, so people do not need to re-characterize the property of chemical A for one product in order to use the present invention to replace the prior art.

3. Chemical A is commercially available, and chemical A′ is part of chemical A. Usually, chemical A′ is the solvent portion of chemical A, therefore, the cost for producing chemical A′ is easy to be kept in a reasonable price.

4. In a preferred embodiment, the process chamber is kept in a saturated vapor pressure by utilizing the vaporized chemical A′. Therefore, the dispensed chemical A can be kept on substrate surface in a certain constituent due to the solvent inside the chemical A will not decrease on the wafer edge since the solvent is achieved in balance inside the process chamber. This can solve the problem of film non-uniformity in the prior art process, and also achieve the purpose of lower cost production since the dispensed amount of chemical A can be reduced.

5. The process can be achieved in a non-rotated substrate since the chemical A′ is vaporized and is easily to be uniformly distributed on the substrate.

Although illustrated and described herein with reference to certain specific embodiments, the present invention is nevertheless not intended to be limited to the details shown. Rather, various modifications may be made in the details within the scope and range of equivalents of the claims and without departing from the spirit of the invention.

1. A process for treating high aspect ratio structure comprising the steps of
A. providing a substrate having at least one hole with high aspect ratio of depth-to-width in said substrate and an opening on said surface;
B. exposing said substrate to a precursory gaseous chemical so that the gaseous chemical condenses on and pre-wets both the top surface of said substrate and the wall surfaces inside said hole due to temperature difference between the substrate and the gaseous chemical;
C. applying a liquid chemical to spread over both the surface of the substrate and the wall surfaces inside the hole pre-wet in step A for further treatment selected from the group consisting of cleaning, etching, coating and developing, wherein said liquid chemical contains at least one component in common with the gaseous chemical in step B.

2. A process as claim in claim 1, where said process is proceeded within a process chamber wherein said gaseous precursory chemical is kept in a state of saturated vapor pressure.

3. A process as claimed in claim 1, wherein said substrate keeps rotating during processing.

4. A process as claimed in claim 1, wherein steps B and C are repeated as necessary.

5. A process as claimed in claim 1, wherein the cross-section view of said hole is selected from the group consisting of oval, circular, rectangle and polygon.

6. A process as described in claim 1, wherein said substrate is a semiconductor wafer.

7. A process as described in claim 1, wherein said substrate is a LCD panel.
